(19) United States
(12) Patent Application Publication
(10) Pub. No.: US 2018/0100601 A1
(43) Pub. Date: Apr. 12, 2018

(54) ELECTROLYTIC MEMBRANE VALVE

(71) Applicant: Zepto Life Technology, LLC, St. Paul, MN (US)

(72) Inventors: Gerson R. Aguirre, Minneapolis, MN (US); Belachew Feyssa, Launderdale, MN (US)

(21) Appl. No.: 15/289,170

(22) Filed: Oct. 8, 2016

(51) Int. Cl. F16K 31/02; B41C 1/14; B41F 15/12; B41F 15/08; C23C 14/20; C23C 14/30; C23C 14/34; F16K 99/00

(52) U.S. Cl. CPC F16K 31/02; B41C 1/145; B41F 15/12; B41F 15/0804; C23C 14/205; F16K 2099/0073; C23C 14/34; F16K 99/0015; F16K 99/003; F16K 99/0042; C23C 14/30

(57) ABSTRACT

An electrolytic membrane valve and method of its manufacture are provided. The valve includes a substrate comprising an opening and a conductive membrane impermeable to a conductive media and sealing the opening, as well as a cathode on the substrate and in communication with the membrane through the conductive media, and an anode on the substrate directly contacting the membrane. The anode is at least partially protected from electrochemical corrosion, and upon application of an electrical potential between the anode and the cathode, the membrane ruptures to allow flow of the conductive media through the opening.

### BACKGROUND

The present disclosure relates in general to devices and methods for controlling the release or passage of a fluid, and more particularly, to valves that can be used, for example, to obstruct an aperture or passageway, and allow the passage of a confined or blocked fluid through the aperture or passageway when a voltage is applied to electrolytically degrade a conductive valve material.

In medical diagnostic devices or drug delivery devices, for example, it is often necessary to control the release of multiple aliquots or serial liquid disbursements at predefined times or intervals through separate apertures or microchannels. To accomplish this, various valve and pump technologies have been developed that utilize, for example, flexible sternums, pneumatics, complex capillary systems, heat or light actuated polymers, rigid beads, or melt expandable materials to drive a fluid through a channel and/or block the passage of a fluid. However, most of these systems either require bulky and expensive actuation peripherals limited to benchtop use, or are not sufficiently robust and reliable for use in portable handheld diagnostic devices or implantable drug delivery devices, for example.

In some microfluidic devices, a microchip has been designed having a reservoir containing a liquid that is blocked from release by an electrically conductive cap material. Upon application of an electrical current through the cap, the cap electrolytically degrades and eventually ruptures, releasing the fluid contents of the reservoir. However, such devices require expensive and cumbersome cleanroom microfabrication techniques, and are designed on a non-flexible substrate, thereby limiting the ability to produce the devices using various low cost high throughput manufacturing techniques including foil technologies, roll-to-roll printing, thermoforming, hot embossing, and injection molding, to name a few. Furthermore, in prior electrolytic valve devices, the anode and cap share the same contiguous structure (i.e. the anode also functions as the cap itself), and thus electrolysis of the cap is the same as electrolysis of the entire anode structure, resulting in substantial gas bubble formation which can interfere with the electrolysis as well as send bubbles into microchannels where they may potentially interfere with downstream assays, for example.

### SUMMARY

The present disclosure relates to an electrolytic valve and method for controlling the release or passage of a fluid, and in another aspect relates to methods for manufacturing such valves.

In one aspect, an electrolytic valve comprises a substrate comprising an opening; a conductive membrane impermeable to a conductive media and sealing the opening; a cathode on the substrate and in communication with the membrane through the conductive media; an anode on the substrate and directly contacting the membrane; wherein the anode is at least partially protected from electrochemical corrosion, and wherein upon application of an electrical potential between the anode and the cathode, the membrane corrodes to allow flow of the conductive media through the opening.

In another aspect, a method of manufacturing an electrolytic valve comprises depositing a conductive membrane onto a substrate over an opening in the substrate; printing an anode onto the substrate so that it partially overlaps a region of the membrane to hold the membrane against the substrate and seal the opening; printing a cathode onto the substrate proximal but separate from the anode and the membrane; enclosing the anode, membrane, and cathode inside of a reservoir joined to the substrate; and providing a conductive media inside the reservoir and in contact with the anode, membrane and cathode.

### BRIEF DESCRIPTION OF THE DRAWINGS

FIG. 1 is a disassembled perspective view of a valve system in accordance with some embodiments.

FIG. 2 is an assembled view of the valve system of FIG. 1

FIG. 3 is a top view of a valve system in accordance with some embodiments.

FIG. 4 is a cross sectional view of FIG. 3.

FIG. 5 is a perspective view of an example application of a valve system in accordance with some embodiments.

FIG. 6 is a line graph showing an effect of applied voltage on gold valve membrane rupture in different conductive media.

FIG. 7 is a line graph showing an effect of applied voltage on aluminum valve membrane rupture in different conductive media.

FIG. 8 is a line graph showing an effect of cesium chloride concentration on gold and aluminum valve membrane rupture.

FIG. 9 is a line graph showing an effect of applied voltage on gold and aluminum valve membrane rupture in the presence of cesium chloride.

FIG. 10 is a line graph showing an effect of cesium chloride concentration on aluminum membrane rupture when a silver and carbon ink mixture electrode is used.

### DETAILED DESCRIPTION

Disclosed herein is an electrolytic valve with improved functionality and reliability, yet can be manufactured using inexpensive materials and is compatible with scalable, rapid assembly methods. Furthermore, due to its compact construction, single-use design and low voltage input requirements, the valve is well-adapted for use in portable platforms utilizing pressure driven microfluidic systems, such as handheld lab-on-a-chip diagnostic devices, for example. Accordingly, the presently described valve has the potential to drive the replacement of costly, existing fluidic delivery systems having limited manufacturing and assembly capabilities as well as burdensome actuation equipment. The valve is furthermore suitable for use in a wide variety of systems and applications including but not limited to: microfluidic or mesofluidic assays; detection systems requiring delivery of liquids of any type; cell trapping or cell release; reagent or analyte storage; mixing of liquids; PCR; genomic analysis; proteomic analysis; microarrays; electrochemistry systems; and implantable as well as wearable technologies. Further advantages of the inventive electrolytic valve, its method of operation and method of manufacture may be appreciated with reference to the following described embodiments.

FIG. 1 is a perspective view showing various components that may be associated with valve system 10 in a disassembled state for easy reference, including substrate 100 having opening 102; membrane 200; cathode 300 having cathode lead portion 302 and arced portion 304, and anode 400 having anode lead portion 402 and anode aperture 404 (collectively “electrodes”); and insulation layer 500 having membrane cutaway 502 and cathode cutaway 504.

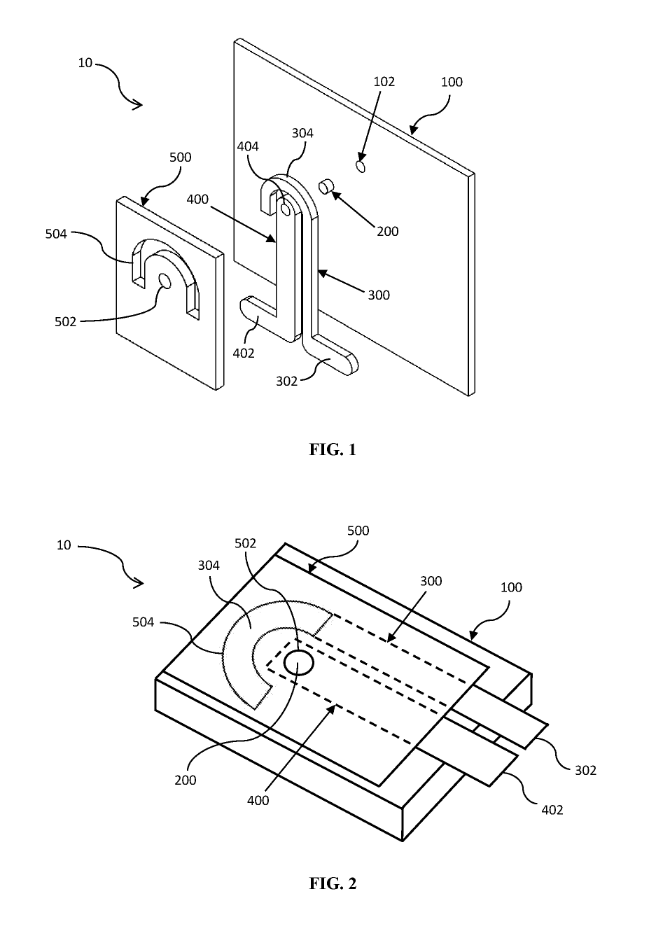

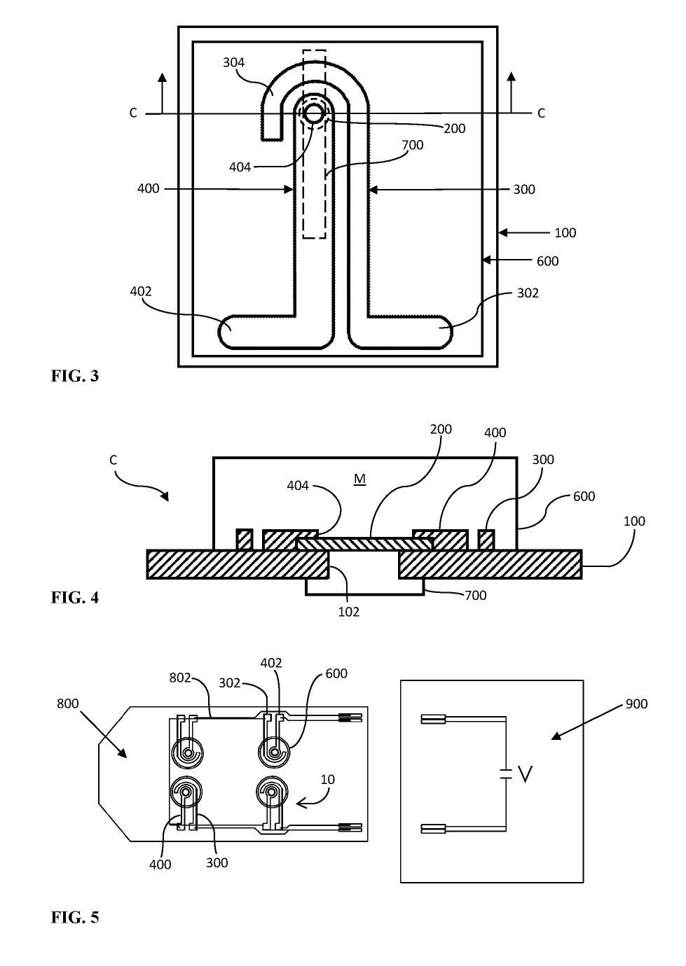

FIG. 2 is a perspective view of an assembled valve system 10 comprising the components shown in FIG. 1. In the assembled state, membrane 200 seals opening 102 of substrate 100. Anode 400 is adhered or otherwise bonded to the surface of substrate 100 such that anode aperture 404 is aligned with opening 102 on the opposite side of membrane 200, and such that at least a portion of anode 400 is in direct contact with membrane 200 near anode aperture 404. Cathode 300 is also adhered or otherwise bonded to the surface of substrate 100 as near as possible to anode 400 but not in direct physical contact with anode 400 so as to avoid potential short circuiting during operation of valve system 10. Reservoir 600 holding a conductive media M (features shown, for example, with reference to FIGS. 3 and 4) provides a conductive path between cathode 300 and anode 400, such that when voltage is applied across the electrodes via cathode lead portion 302 and anode lead portion 402 connected to a power source (shown, for example, with reference to FIG. 5), the electromotive force of the electrodes holds the electrical potential of anode 400 at a level sufficient for corroding the conductive material of membrane 200 and causing it to rupture within an acceptable time frame, thereby allowing the passage of conductive media M through opening 102.

In one embodiment, insulation layer 500 is further provided and is layered over cathode 300 and anode 400 such that the electrodes are sandwiched between insulation layer 400 and substrate 100 to at least partially insulate anode 400 from conductive media M, while still exposing membrane 200 and cathode arced portion 304 to media M via membrane cutaway 502 and cathode cutaway 504, respectively. Alternatively, insulation layer 400 may also be applied such that it substantially or completely insulates anode 400 from conductive media M, depending on the particular requirements of valve system 10 as discussed hereinafter. Accordingly when valve system 10 is actuated via application of a voltage potential across the electrodes, anode 400 is protected from corrosion, thereby minimizing or in some cases eliminating the formation of hydrogen and oxygen gas bubbles resulting from anodic oxidation. Such bubbles can not only interfere with and delay the controlled corrosion of membrane 200, but can also interfere with the flow of reservoir fluid through downstream microchannels (such as feature 700 shown in FIGS. 3 and 4), thereby hindering assays or other functions of an apparatus utilizing the electrolytic valve. Insulation layer 500 further functions to promote more efficient corrosion of membrane 200 by focusing the electrical field between the arced portion 304 of cathode 300 and membrane 200 closest to where anode 400 is in direct contact with membrane 200.

FIGS. 3 and 4 are additional views of an embodiment of valve system 10 but without insulation layer 500, FIG. 3 representing a top view of valve system 10 and FIG. 4 showing cross section C of FIG. 3. Further shown is reservoir 600 joined to substrate 100 for holding conductive media M and over cathode 300 and anode 400 such that they are in contact with the conductive media M, and also further showing valve 200 held underneath a portion of anode 400. To show how valve system 10 relates to a microfluidic device, microchannel 700 of a microfluidic device is shown underneath substrate 100 and in communication with opening 102. When membrane 200 is electrolytically ruptured as described previously, the contents of conductive media M are then allowed to flow through anode aperture 404 and substrate opening 102 into microchannel 700.

As can be appreciated from FIGS. 3 and 4, the perimeter of membrane 200 extends beyond the perimeter of anode aperture 404 (i.e. the diameter of membrane 200 is larger than the diameter of aperture 404), such that a portion of anode 400 overlaps the whole perimeter of membrane 200, thereby maximizing the conductive contact between anode 400 and membrane 200, as well as facilitating even corrosion of membrane 200 from the entire perimeter. Further, cathode 300 is configured such that arced portion 304 arcs circumferentially around an axis defined by a center point of membrane 200, thereby focusing the electromagnetic field emanating from cathode 300 on membrane 200 to further maximize its corrosion. Although cathode 300 and anode 400 are shown residing in substantially the same two dimensional plane, it may be appreciated that other configurations are also suitable for driving electrolytic corrosion of membrane 200, including an arrangement where cathode 300 and anode 400 are oriented in a top-to-bottom relationship, for example.

In one embodiment, anode 400 is adhered or otherwise bonded to the surface of substrate 100, while the overlap of anode 400 around a perimeter of membrane 200 functions to physically hold membrane 200 against opening 102 to seal it and prevent the passage of liquid contents, such as conductive media M, from reservoir 600. Although a perimeter of membrane 200 may also be physically adhered or otherwise bonded to a region surrounding opening 102, the relatively small bonded surface area may be insufficient to keep membrane 200 sealed against opening 102 over time or under microfluidic pressure, particularly when substrate 100 is a flexible substrate subjected to bending stresses during roll-to-roll fabrication or other high-throughput manufacturing techniques. In contrast, the relatively large bonded surface area of anode 400 to substrate 100 and the substantial overlap of anode 400 around a perimeter of membrane 200 provides a superior mechanism for physically holding membrane 200 against opening 102 so as to seal it, and without requiring the use of adhesives, bonding techniques or additional assembly steps.

In one embodiment, membrane 200 is placed over opening 102, and then anode 400 is inkjet or screen printed onto the surface of substrate 100 and in a manner overlapping the perimeter of membrane 200 as described previously. Cathode 400 may also be inkjet or screen printed onto substrate 100. In such case, membrane 200 was surprisingly found to maintain its seal under microfluidic pressure, and there was no detaching or delamination of anode 400 or cathode 300 even when substrate 100 was repeatedly flexed at an angle of 180 degrees under test conditions. Accordingly valve system 10 may be utilized in rigorous high-throughput manufacturing or assembly processes requiring flexing of substrate 100, and may also benefit microfluidics designs requiring flexible valve configurations.

FIG. 5 is an embodiment showing an example use of valve system 10, whereby multiple valve systems 10 are employed on a single PCB 800 and electrically connected via electrical paths 802 communicating with cathode and anode lead portions 302, 402 respectively. Each valve system 10 comprises a reservoir 600, and each reservoir 600 comprises a conductive media M. Each conductive media M may comprise, for example, a constituent such as a reagent, analyte, drug, biocompatible fluid, bodily fluid, cell, protein, antibody, antigen, or nucleic acid. Valve systems 10 are each attached or printed directly onto a microfluidic system, and their anodic and cathodic leads are connected to electrical paths 802 designed on PCB 800 for connectivity to applied potential from power source 900. Firmware, specifically written to control each path, or alternatively controlled manually by a user, is used to deliver electrical potential at given sequential intervals to each valve system 10, thereby effecting corrosion of the membrane 200 in each valve system 10, and releasing the contents of conductive media M into a microchannel, for example. At the end of the time interval for a given individual membrane 200 to corrode, PCB 800 is actuated to deliver an electrical potential to the next valve system 10, and release the contents from its associated reservoir 600.

Suitable substrates 100 for use with the electrolytic valve system 10 include but are not limited to: etched silicon such as wafers or foils; glass such as slides, cover slips or flexible glass materials; plastics such as elastomeric, thermoplastic elastomers, elastic or thermoelastic; flexible silicon or liquid silicon rubber; or any solid substrate designed for holding or delivering fluids or liquids. The use of flexible substrates with valve system 10 enables incorporation of the system into numerous high throughput manufacturing and assembly techniques requiring mechanical flexibility during processing or handling, as described previously.

The electrodes, either anode 400, cathode 300, or both, are preferably inkjet printed or screen printed directly onto substrate 100, and suitably utilize a conductive ink. Preferably carbon based inks are utilized comprising a conductive material in an amount of about 50% w/w, for example. Suitable conductive materials may include but are not limited to silver, gold, aluminum, titanium, copper, carbon nanotubes, graphene, conductive polymers, or a combination thereof. It was discovered that carbon based inks have better bonding to flexible substrates than pure metal inks. Furthermore, by utilizing a carbon based ink and adjusting the optimal content of the conductive material added to the ink, a balance between sufficient conductivity and anodic resistance to oxidation may be achieved to both drive corrosion of membrane 200 while also minimizing the formation of gas bubbles to an acceptable and non-interfering level. Accordingly, with the proper selection of ink composition, anode 400 may be at least partially protected from corrosion, and insulation layer 500 may be optionally utilized rather than required.

In addition, inkjet printing is a technology that can easily be scaled and is more comparable to manufacturing such as roll-to-roll processes, droplet on demand, and spray coating onto a substrate which may or may not contain features other than membrane 200. Nonetheless, it may be appreciated that alternative electrode deposition methods may also be utilized, including but not limited to sputtering, flexography, gravure, microelectric processing techniques including chemical vapor deposition, electron beam evaporation, and reactive ion etching, for example. Drying techniques can also be used in roll-to-roll at high web speeds, where heating, UV curing and photonic sintering can be utilized to manufacture the electrodes.

Suitable materials for insulation layer 500 include any non-conductive and preferably flexible material. For high throughput manufacturing, insulation layer may be deposited using the same techniques as described for deposition of the electrodes of valve system 10. The material should impart the same physical and mechanical parameters considered as insulating.

Suitable materials for membrane 200 may include any metals that can be corroded by electrolysis, including but not limited to gold, aluminum, copper, titanium, platinum, chromium, silver, nickel, tantalum, zinc, tungsten, molybdenum, and palladium. Suitable membrane 200 deposition methods onto substrate 100 include but are not limited to transfer by adhesive, gluing, sputtering, brushing metal foil, and pick and place. Suitable membrane 200 thicknesses are in general from about 400 nm to about 500 μm, and the membrane should be impermeable to the conductive media M. For aluminum a preferred thickness is between about 7 μm to about 500 μm, and for gold a preferred thickness is between about 400 nm to about 1 μm. Membrane 200, when comprising aluminum, was found to stably withstand a load corresponding to a liquid flow rate of 5 mL/min through opening 102 without rupturing, or alternatively a microfluidic pressure of 2.0 Pa/mm² under actual test conditions, thereby making it suitable for almost any microfluidic, bioreactor or any fluid delivery devices constituting these physical parameters including but not limited to diagnostic devices.

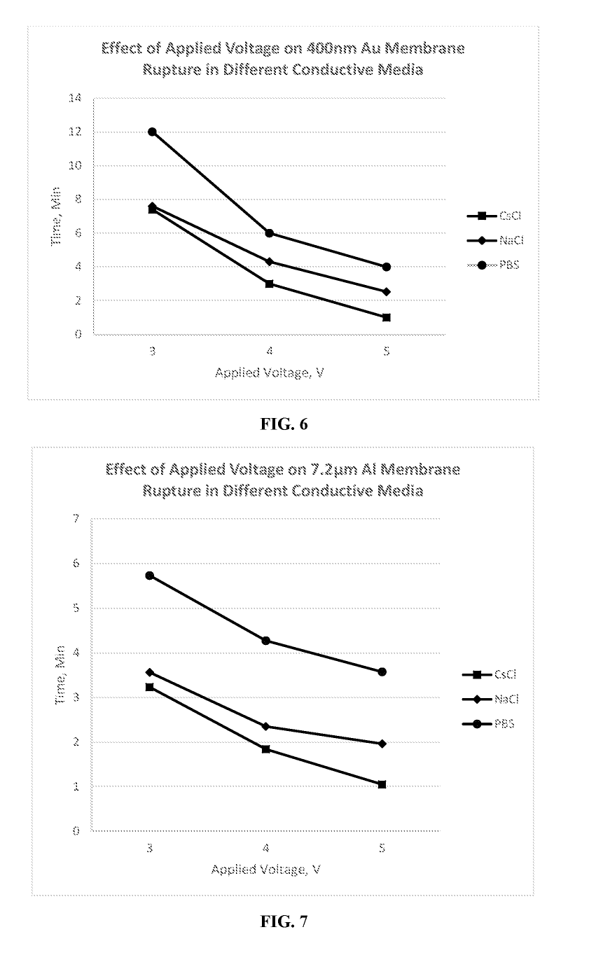

A suitable conductive media M is any media containing electrolytes sufficient for closing the electrical system and with sufficient ionic strength to drive corrosion of membrane 200 upon delivery of a desired voltage potential to the electrodes. Suitable conductive media may comprise an electrolyte such as sodium, cesium, thiolates, phosphates, amines, amides and cations, or a combination thereof, for example. A preferred media is phosphate buffered saline (PBS), wherein the sodium chloride concentration may be adjusted to increase or decrease ionic strength of the media based on the desired corrosion of membrane 200, for example. Alternatively, cesium chloride may also be used in PBS media to further increase ionic strength and conductivity and promote rapid electrolytic disintegration of membrane 200 with less required voltage, as described with reference to FIGS. 6-10, for example. Furthermore, in the case of medical or diagnostic applications, the conductive media M is also preferably biocompatible, and may comprise a constituent such as a reagent, analyte, drug, biocompatible fluid, bodily fluid, cell, protein, antibody, antigen, or nucleic acid, for example.

Valve system 10 may have a functional voltage input range from about 0.5V to about 10V, more preferably between about 3V and about 5V, wherein membrane 200 preferably ruptures before about 12 minutes, more preferably before about 1 to about 3 minutes, and most preferably under 1 minute under actual operating conditions. However, it may be appreciated that based on routine skill in the art and with reference to the disclosures provided herein, a sufficient input voltage for membrane 200 corrosion may be flexibly established based on adjustments and choices made regarding composition of the electrode, membrane, and media as well as the desired membrane 200 rupture time. In one example provided below, an optimal voltage of about 4V was established to drive sufficient corrosion of membrane 200, thereby enabling use of valve system 10 in portable diagnostic devices having a maximum power source of 5V, for example. Furthermore, it should be cautioned that the higher the voltage, the higher the likelihood of anodic corrosion and gas bubble formation, and therefore in applications where anode 400 is only partially protected from corrosion, lower voltages may be preferable.

In another embodiment, the electrolytic valve system 10 may be manufactured according to a method comprising: depositing conductive membrane 200 onto substrate 100 over opening 102 in substrate 100; printing anode 400 onto substrate 100 so that it partially overlaps a region of membrane 200 to hold membrane 200 against substrate 100 and seal opening 102; printing cathode 300 onto substrate 100 proximal but separate from anode 400 and membrane 200; enclosing anode 400, membrane 200, and cathode 300 inside of reservoir 600 joined to substrate 100; and providing conductive media M inside reservoir 600 and in contact with anode 400 (if insulation layer 500 is not utilized), membrane 200 and cathode 300. Suitable printing methods include but are not limited to inkjet printing, screen printing, flexography, gravure, or sputtering.

### Electrolytic Valve Lab Fabrication Method

The resources utilized for fabricating the electrolytic valve in the lab included: Digital Craft Cutter (Sihouette America, Inc, Sihouette Cameo™); UV Vacuum digital exposure unit with automatic curing timer (VEVOR, Shanghai Sishun E-commerce Co., Ltd); Draw down platform for coating PVA on acetate film (Diversified Enterprises, Claremont, N.H., USA); Programmable voltage power supplier (National Instruments Cop., Austin, Tex.); Solidworks design software (Solidwork, Dassault Systemes Solideorkes Cop., Massachusetts); 20″×24″×½″ base 110 monofilament mesh screen printing unit with wood frame, cast hinge clamps and 10″ squeegee (Dick Blick art Materials, IL); Diazo Screen Printing Exposure Kits (Speedball Art Product; statesville, NC); Highly flexible Clear dielectric (Creative materials Inc., MA); Clear, flexible epoxy dielectric for ITO (Creative materials Inc., MA); Ercon carbon ink (No E3455), Ercon Silver ink (No E1660), Ercon blue insulayer (No E6165) (Ercon, Waltham, Mass.); Sheet of Cellulose Acetate (Overhead transparency films, Staples®); Conductive copper foil tape with conductive adhesive (Kit Hub Inc., LA); Removable Tape (Scotch® 811, 3M); Polyvinyl Alcohol (School glue, Elmer's®); 0.05 mm 99.99% Aluminum Foil (Alfa Aesar Inc., MA); and Double-sided PSA tape (McMaster).

To fabricate the electrodes, first a metal membrane was patterned. Thin metal foil to be used as anodic membrane can be patterned on plastic substrates manually. First the desired electrode pattern was designed using Solidworks or CAD and saved as a DXF file. After designing the electrode pattern the image can be printed on a Mylar sheet with inkjet printing, or alternatively screen printed as described herein. The file was opened in the Silhouette Craft Cutter program. Double sided PSA tape was cut into 170 mm×60 mm rectangular pieces. One of the covering films was removed and each peace attached on a Cellulose acetate sheet. A pattern of 1.4 mm diameter holes on the plastic film and adhesive tape assembly were made using a knife cutter insuring that the pattern perfectly matched the original electrode pattern. Then a pattern of 3 mm×3 mm rectangles was made using a knife cutter so that each rectangle surrounded the 1.4 mm hole at the center.

A 0.4 μm gold film was prepared by sputtering or Electron beam evaporation on acetate film with a draw down coating platform. A 3 mm×3 mm rectangular pattern on the gold side of gold sputtered acetate film was made using a knife cutter. Then each rectangular gold pattern was aligned and pressed to PSA tape patterned acetate film and lifted off. The PSA tape patterned acetate film was continued to be filled with the gold film until completed.

The aluminum based electrolysis valve was made using commercially available aluminum foil. The aluminum foil patterning process was similar to gold patterning process. First the double sided PSA tape was covered with a removable tape. Then a 50 μm aluminum foil was overlaid and carefully pressed with a rubber roller to get a flat aluminum film. A 3 mm×3 mm rectangular pattern was made on the aluminum/PSA tape assembly using a knife cutter. Then the PSA tape pattern was aligned and pressed as described earlier and lifted off.

Electrodes were deposited using a screen print method. To prepare a photo emulsion, a Diazo Sensitizer bottle was filled with ¾ full cold water and then shaken well. The contents of the Diazo Sensitizer bottle were poured into the photo emulsion container and then thoroughly mixed in a dark room until all the photo emulsion was a uniform color.

To coat the screen, an appropriate quantity of emulsion was poured across one end of the screen. A squeegee was used to spread it evenly over the whole screen, making a uniform and thin layer. The screen was flipped over and another appropriate quantity of emulsion was applied on one end of the inside of the screen and spread evenly over the screen with the squeegee. The process was repeated until a thin, even layer of emulsion covering the entire screen was achieved. The screen was then set in a dark place to dry. To prepare the electrodes pattern image, and to get the image on the screen, a positive mask was used.

To expose the screen, the exposure unit was set for a vacuum of 500 seconds and an exposure time of 600 seconds. Once the vacuum and exposure parameters were set, a dry sensitized screen was placed bottom side up. The transparency image was placed on the screen and attached with transparent adhesive tape. The screen was then placed for exposure. Once the exposure was finished, the transparency was removed, and then the screen was rinsed to remove the non-polymerized emulsion.

For carbon ink deposition, it was first ensured that no pinhole or spots on the image pattern were visible under bright light. The aluminum foil patterned acetate sheet was attached on the screen with removable tape after precisely aligning the metal film pattern with the electrode pattern on the screen. An appropriate quantity of carbon ink was placed on one side of the screen, and then drawn with a squeegee. The printed carbon ink was dried on a hot plate for 5 min at 121° C. The resistance of the printed carbon was then measured, and had a typical value of 210n.

To deposit a silver and carbon ink mixture, silver ink was stirred in its container for 2 min. The desired amount of silver ink was weighed and an equal amount of carbon ink was added to make a 50% Carbon/50% Silver ink (Ag50 ink). The two inks were mixed thoroughly until the color of the content was uniform. The gold membrane patterned plastic sheet was attached on the screen with removable tape after precisely aligning the metal film pattern with the electrode pattern on the screen. An appropriate amount of the Ag50 ink was then placed on the screen and pulled/drawn firmly. The printed ink was then dried at 121° C. for 5 min on a hot plate and the resistance of the printed Ag50 ink layer was measured with a typical resistance value between 1.5 to 2.0Ω.

To deposit an insulation layer, after preparation of the insulation layer screen, the carbon or Ag50 ink patterned acetate sheet was precisely attached so that the electrode pattern matched perfectly with the insulation layer pattern on the screen. The insulation layer material was stirred thoroughly, and then an appropriate amount of the material was placed on one side of the screen and drawn firmly with a squeegee, following by drying on a hot plate at 111° C. for 5 min.

### Example 1—Effect of Applied Voltage on 400 nm Au Membrane Rupture in Different Conductive Media

A gold film having a thickness of 400 nm and diameter of 1.4 mm was used as a valve membrane in conjunction with electrodes having a mixture of silver and carbon inks (50% w/w). PBS buffer was used as a baseline conductive media comprising 0.05% Tween 20. NaCl conductive media was prepared by the addition of 0.4M NaCl to the PBS buffer. CsCl conductive media was prepared by the addition of 0.4M CsCl to the PBS buffer. Varying voltages of 3, 4 and 5 volts were applied across the electrodes composed of 50% carbon ink and 50% silver ink to corrode the gold membrane in the presence of each conductive media, and average time to membrane rupture was measured for each conductive media. The results are shown in Table 1 below, as well as represented in FIG. 6.

TABLE 1

| Voltage | CsCl | NaCl | PBS |
|---|---|---|---|
| 3 | 3.23 | 3.56 | 5.73 |
| 4 | 1.84 | 2.35 | 4.27 |
| 5 | 1.05 | 1.96 | 3.57 |

As can be appreciated from the results, increasing the concentration of either sodium or cesium ions shows an improved corrosion of the membrane. At 3 volts, the effect is similar for the two ions, however, as more voltage is applied, the accelerated corrosion of the membrane is more pronounced for cesium. At a typical max voltage of a handheld device (5 volts), in the presence of cesium chloride the membrane degrades in as little as one minute from initial application of the voltage, thus making it a suitable candidate for improving the valve performance in such devices.

### Example 2—Effect of Applied Voltage on 7.2 μm Al Membrane Rupture in Different Conductive Media

An aluminum film having a thickness of 7.2 μm and diameter of 1.4 mm was used as a valve membrane in conjunction with electrodes composed of a mixture of silver and carbon inks (50% w/w). PBS buffer was used as a baseline conductive media comprising 0.05% Tween 20. NaCl conductive media was prepared by the addition of 0.4M NaCl to the PBS buffer. CsCl conductive media was prepared by the addition of 0.4M CsCl to the PBS buffer. Varying voltages of 3, 4 and 5 volts were applied across the electrodes to corrode the aluminum membrane in the presence of each conductive media, and average time to membrane rupture was measured for each conductive media. The results are shown in Table 2 below, as well as represented in FIG. 7.

TABLE 2

| Voltage | CsCl | NaCl | PBS |
|---|---|---|---|
| 3 | 7.4 | 7.6 | 12 |
| 4 | 3.01 | 4.31 | 6 |
| 5 | 1.01 | 2.53 | 4 |

As can be appreciated from the results, increasing the concentration of either sodium or cesium ions shows an improved corrosion of the membrane. However, compared with the gold membrane and the results of Table 1 and FIG. 6, the aluminum membrane surprisingly outperforms gold by corroding at nearly twice the rate at 3 volts with only slightly diminished effect at 4 volts in any of the conductive media, but with a diminishing effect at higher voltages. This is surprising considering that the pure carbon ink is less conductive than the mixture containing 50% silver ink. Accordingly, when operating at 5 volts, there is a negligible corrosion performance difference between the gold and aluminum membranes in the presence of different conductive media. However, when considering the thickness of the tested aluminum membrane was 18 times thicker than the tested gold membrane, yet the corrosion time of one minute was the same for both membranes at 5 volts, indicates the superior electrolytic behavior of the aluminum membrane.

### Example 3—Effect of CsCl Concentration on 7.2 μm Al and 400 nm Au Membrane Rupture at 4V

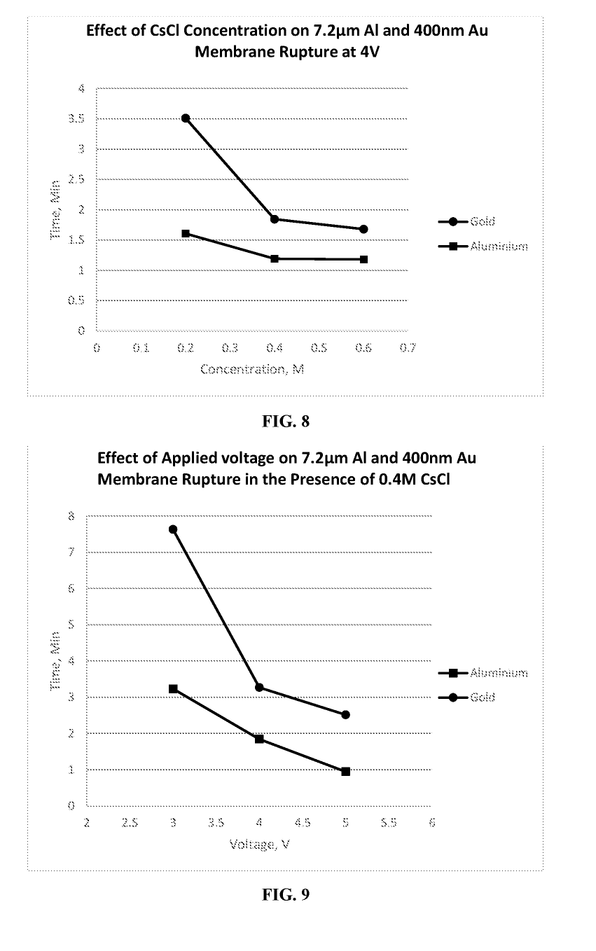

An aluminum film having a thickness of 7.2 μm and a gold film having a thickness of 400 nm, each with a diameter of 1.4 mm, was used as a valve membrane in conjunction with electrodes comprising screen printed carbon ink for aluminum and a screen printed mixture of silver and carbon inks (50% w/w) for gold. Conductive CsCl media having varying ionic strengths was prepared by the addition of 0.2M to 0.6M CsCl to PBS buffer. A fixed voltage of 4 volts was applied across the electrodes to corrode the membranes in the presence of each varying CsCl concentration conductive media, and average time to membrane rupture was measured. The results are shown in Table 3 below, as well as represented in FIG. 8.

TABLE 3

| | Au | Al |
|---|---|---|
| CsCl Concentration (M) | Time to Rupture (min) | Time to Rupture (min) |
| 0.2 | 3.51 | 1.6 |
| 0.4 | 1.84 | 1.19 |
| 0.6 | 1.68 | 1.18 |

As can be appreciated from the results, at a minimal added cesium chloride concentration of 0.2M, the time to membrane rupture for gold was over twice as long as aluminum, however, at increasing cesium chloride concentrations, the difference in time to rupture was more negligible. Accordingly, the beneficial effect of cesium chloride on corrosion performance of either membrane with their respective electrode ink compositions may be achieved with only a small amount of the ion added to PBS buffer. However, as would be expected based on the results of Examples 1 and 2, aluminum continued to outperform gold at each concentration of cesium chloride.

### Example 4—Effect of Applied Voltage on 7.2 μm Al and 400 nm Au Membrane Rupture in the Presence of CsCl

An aluminum film having a thickness of 7.2 μm and a gold film having a thickness of 400 nm, each with a diameter of 1.4 mm, was used as a valve membrane in conjunction with electrodes comprising screen printed carbon ink for aluminum and a screen printed mixture of silver and carbon inks (50% w/w) for gold. Conductive CsCl media was prepared by adding 0.4M CsCl to PBS buffer. Varying voltages of 3, 4 and 5 volts were applied across the electrodes to corrode the membranes in the presence of the conductive media, and average time to membrane rupture was measured at each voltage. The results are shown in Table 4 below, as well as represented in FIG. 9.

TABLE 4

| | Au | Al |
|---|---|---|
| Voltage (V) | Time to Rupture (min) | Time to Rupture (min) |
| 3 | 7.63 | 3.23 |
| 4 | 3.26 | 1.84 |
| 5 | 2.51 | 0.94 |

As can be appreciated from the results, the aluminum membrane once again outperformed the gold membrane, showing over twice the average corrosion over the range of 3 to 5 volts considering that the carbon ink is not as conductive as the mixture of silver ink and carbon ink.

### Example 5—Effect of CsCl Concentration on Al Membrane Rupture with a Silver and Carbon Ink Mixture Electrode

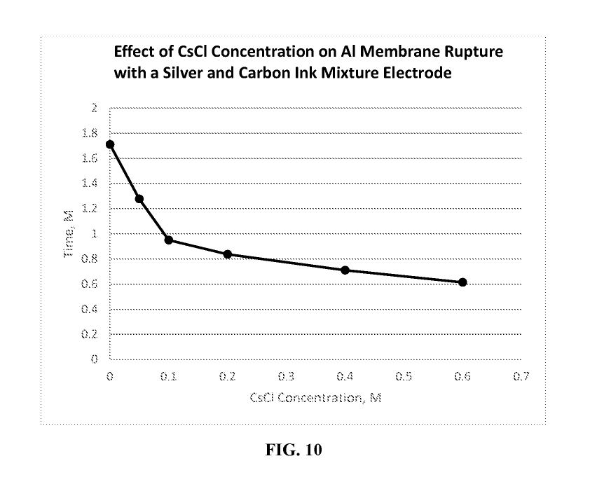

An aluminum film having a thickness of 7.2 μm and a diameter of 1.4 mm was used as a valve membrane in conjunction with electrodes comprising a screen printed mixture of silver and carbon inks (50% w/w). PBS was used as a baseline zero measurement, with increasing amounts of CsCl added to the PBS buffer from 0.05M to 0.6M. A fixed voltage of 4 volts was applied across the electrodes to corrode the aluminum membrane in the presence of each media having different ionic strengths, and average time to membrane rupture was measured. The results are shown in Table 5 below, as well as represented in FIG. 10.

TABLE 5

| CsCl Concentration (M) | Time to Rupture (min) |
|---|---|
| 0 | 1.71 |
| 0.05 | 1.27 |
| 0.1 | 0.95 |
| 0.2 | 0.84 |
| 0.4 | 0.71 |
| 0.6 | 0.61 |

As can be appreciated from the results, the aluminum membrane's performance under ionic strength of CsCl and using a 50% silver ink and 50% carbon ink electrode is much faster than gold with the same electrode as well as aluminum with only a carbon electrode, showing over 60% faster corrosion of the aluminum membrane, while for gold a 75% faster corrosion under the exact same conditions. The data shows that under these conditions the membrane corrosion should not be the rate-limiting factor in certain applications utilizing molecular biology, such as digital microfluidics where polymerase chain reaction (PCR) cycles can be achieved in minutes. The invention described herein can be used for delivering multiple analytes during these cycling.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. An electrolytic valve comprising:
a substrate comprising an opening;
a conductive membrane impermeable to a conductive media and sealing the opening;
a cathode on the substrate and in communication with the membrane through the conductive media;
an anode on the substrate and directly contacting the membrane;
wherein the anode is at least partially protected from electrochemical corrosion; and
wherein upon application of an electrical potential between the anode and the cathode, the membrane ruptures to allow flow of the conductive media through the opening.

2. The electrolytic valve of claim 1, wherein either of the anode or cathode are printed onto the substrate.

3. The electrolytic valve of claim 1, wherein the anode comprises a carbon-based ink comprising a conductive material.

4. The electrolytic valve of claim 2, wherein the anode is printed onto the substrate such that the anode partially overlaps the membrane and physically holds the membrane against a surface of the substrate and over the opening.

5. The electrolytic valve of claim 1, wherein the anode overlaps the membrane around a perimeter of the membrane.

6. The electrolytic valve of claim 1, wherein at least a portion of the cathode arcs circumferentially around an axis defined by a center point of the membrane.

7. The electrolytic valve of claim 4, wherein the substrate is flexible, and the cathode and anode remain stably adhered to the substrate along with the membrane when the substrate is flexed up to 180 degrees.

8. The electrolytic valve of claim 7, wherein the flexible substrate comprises a material selected from the group consisting of a plastic, thermoplastic, elastomer, rubber, liquid silicone rubber, thermoelastic material, flexible silicon, thermoplastic elastomer.

9. The electrolytic valve of claim 1, wherein the membrane further comprises a metal selected from the group consisting of gold, aluminum, copper, titanium, platinum, chromium, silver, nickel, tantalum, zinc, tungsten, molybdenum, and palladium.

10. The electrolytic valve of claim 9, wherein the membrane comprises aluminum, and wherein the membrane can stably withstand a load corresponding to a liquid flow rate of 5 mL/min through the opening without rupturing.

11. The electrolytic valve of claim 3, wherein the conductive material is in an amount of about 50% w/w.

12. The electrolytic valve of claim 11, wherein the conductive material is selected from the group consisting of silver, gold, aluminum, titanium, copper, carbon nanotubes, graphene, conductive polymers.

13. The electrolytic valve of claim 1, wherein the membrane comprises one of aluminum having a thickness of between about 7 μm to about 500 μm, or gold having a thickness of between about 400 nm to about 1 μm.

14. The electrolytic valve of claim 13, wherein the conductive media further comprises an electrolyte selected from the group consisting of sodium, cesium, thiolates, phosphates, amines, amides and cations.

15. The electrolytic valve of claim 14, wherein the membrane ruptures in under about 12 minutes with the application of electrical potential in a range of about 3 to about 5 volts.

16. The electrolytic valve of claim 14, wherein the membrane ruptures in under 1 minute with the application of electrical potential in a range of about 3 to about 5 volts.

17. The electrolytic valve of claim 1, wherein the conductive media comprises a constituent selected from the group consisting of a reagent, analyte, drug, biocompatible fluid, bodily fluid, cell, protein, antibody, antigen, or nucleic acid.

18. The electrolytic valve of claim 1, further comprising an insulation layer covering at least a portion of the anode to protect it from corrosion.

19. A method of manufacturing an electrolytic valve comprising: depositing a conductive membrane onto a substrate over an opening in the substrate; printing an anode onto the substrate so that it partially overlaps a region of the membrane to hold the membrane against the substrate and seal the opening; printing a cathode onto the substrate proximal but separate from the anode and the membrane; enclosing the anode, membrane, and cathode inside of a reservoir joined to the substrate; and providing a conductive media inside the reservoir and in contact with the anode, membrane and cathode.

20. The method of claim 19, wherein the printing comprises one of inkjet printing, screen printing, sputtering, flexography, and gravure.
